(19) United States
(12) Patent Application Publication
(10) Pub. No.: US 2004/0195673 A1
(43) Pub. Date: Oct. 7, 2004

(54) Thermoelectric device for cooling

(76) Inventor: Michael Zaidman, Jerusalem (IL)

Correspondence Address: LOWE HAUPTMAN GILMAN AND BERNER, LLP, 1700 DIAGONAL ROAD, SUITE 300 /310, ALEXANDRIA, VA, 22314, US

(21) Appl. No.: 10/487,352

(22) PCT Filed: Aug. 15, 2002
(86) PCT No.: PCT/IL02/00676

(30) Foreign Application Priority Data
Aug. 23, 2001 (IL) 145095

(51) Int. Cl. H01L 35/30

(52) U.S. Cl. 257/706

(57) ABSTRACT

A thermoelectric device useful for cooling comprising: a plurality of N-type thermoelectric semiconductor elements; a plurality of P-type thermoelectric semiconductor elements; metal junctions between horizontally adjacent semiconductor elements; special layers between vertically adjacent N-type thermoelectric semiconductor elements and between vertically adjacent P-type thermoelectric semiconductor elements; a cold pole; at least two heat sinks; and a source of direct current power interconnected so as to pump electrons from the N-type semiconductors to the P-type semiconductors, or to pump holes from the P-type semiconductors to the N-type semiconductors, such that the heat buildup is distributed among more than one heat sink.

### FIELD OF THE INVENTION

The present invention generally relates to thermoelectric devices for cooling. More specifically, the present invention relates to a thermoelectric device having one cold pole and at least two heat sinks, wherein said device is useful for cooling.

### BACKGROUND OF THE INVENTION

Thermoelectric devices have thermoelectric materials sandwiched between ceramic plates. They are solid-state, vibration-free, noise-free heat pumps, pumping the heat from one surface to another. If the heat at the hot side is dissipated to the ambient environment, this assembly becomes a cooling unit. A thermoelectric module also can be used to generate electrical power by converting heat from any source.

Having no moving parts, being small in size and light in weight, thermoelectric devices have been widely used in military, medical, industrial, consumer, scientific/laboratory, electro-optic and telecommunications areas for cooling.

Thermoelectric cooling or heating, also called “the Peltier Effect,” is a solid-state method of heat transfer through dissimilar semiconductor materials. Using Bismuth and copper, in 1834 Jean Charles Peltier discovered the flip side of Seebeck's thermoelectric effect. He found that current driven in a circuit made of dissimilar metals causes the different metals to be at different temperatures.

This effect arises in the process of direct current (DC) flowing through a module that leads to the transfer of heat from one side of the module to the other. As a result, one side of the module cools and the other heats. Temperature differences can be achieved up to +73° C. in a single stage module and more than +100° C. in multistage modules.

Advantages of using thermoelectric modules for cooling or heating:

ecological cleanliness and safety due to the absence of any gas or liquid agents;

no noise or vibration;

cooling or heating mode is simply changed by reversing the current flow direction;

miniaturization capabilities, especially with the more recent advent of micro-electromechanical structures (MEMS); and

functionality in any position relative to the gravitation field, including weightlessness.

Thermoelectric cooling uses the following elements:

a cold pole,

a heat sink and

a DC power source.

The cold pole is cooled because the electrons move from the level of energy of one of the semiconductors to the higher level of energy of the second semiconductor. A DC power source pumps the electrons from one semiconductor to another. A heat sink discharges the accumulated heat energy from the system. A thermoelectric device is defined simply as semiconductor materials with dissimilar characteristics, as connected electrically in series and thermally in parallel, so that two junctions are created.

The semiconductor materials are negative (N) and positive (P) type, and are so named because either they have more electrons (−) than necessary to complete a special molecular lattice structure (N-type) or not enough electrons (+) to complete a lattice structure (P-type). The P and N semiconductors are joined with a metallic junction to form a π-type series circuit, called the “P-N thermocouple.” The extra electrons in the N-type material and the holes left in the P-type material are called “carriers” and they are the agents that absorb the heat energy, and move it from the cold pole to the heat sink. Heat absorbed at the cold pole is pumped to the heat sink at a rate proportional to carrier current passing through the circuit and the number of couples.

Good thermoelectric semiconductor materials, such as bismuth telluride, greatly impede conventional heat conduction from hot to cold areas, yet provide an easy flow for the carriers. In addition, these materials have carriers with a capacity for transferring more heat.

Reference is now made to prior art FIG. 1a, which is a combined graph of relative temperature 101 vs. distance 102 from the heat load 104, wherein distances 102 are referenced to a schematic diagram of a thermoelectric device. The upper part of the diagram above illustrates the steady-state temperature profile across a typical thermoelectric device from the load side 104 to the heat released from the heat sink 140 to the ambient environment 106. A P-type semiconductor 120 and an N-type semiconductor 110 are connected via insulators 108 to a cold pole 130 and heat sink 140. A DC power source 115 pumps the electrons from N-type semiconductor 110 to P-type semiconductor 120. The total steady-state heat that must be rejected by the heat sink to the environment may be expressed as follows:

Q_{S}=Q_{C}+V*I+Q_{L}, where:

Q_{S} 106 is the heat rejected;

Q_{C} is the heat absorbed from the load;

V*I is the power input; and

Q_{L} is the heat leakage.

If the heat sink cannot reject enough Q_{S} 106 from the system, the system's temperature will rise and the cold junction temperature will increase. If the emitted heat increases, the cooling effect tends to decrease. Stabilization of the hot pole at 5 to 10 degrees higher than the ambient temperature, by using a good heat sink, and by stabilizing the temperature of the cold pole near the ambient temperature, contributes to improved coefficient of performance (COP).

Energy may be transferred to or from the thermoelectric system by three basic modes: conduction, convection, and radiation. The values of Q_{C} and Q_{L} may be easily estimated; their total, along with the power input, gives Q_{S}, the energy the hot junction heat sink must dissipate.

Prior art FIG. 1b is a simplified schematic illustration of a standard Peltier module 100. Standard module 100 comprises two types of semiconductor elements: N-type semiconductors 110; and P-type semiconductors 120. The main feature of standard module 100 is that the height of the semiconductor elements is equal to the module height 150. The entire top surface of standard module 100 is a heat sink 130, and the entire bottom surface is a cold pole 140. The area of heat sink 130 is equal to the area of cold pole 140.

Prior art FIG. 1c is a schematic diagram of the electricity path 170 through standard module 100. The current traverses N-type semiconductors 110 and P-type semiconductors 120 serially, with intermediary traversals of the metal junctions 180. Thus, the primary feature of electrical path 170 through standard module 100 is the regular alternations: semiconductor—metal junction—semiconductor—metal junction.

Thus, it would be desirable to provide an improved and diversified system and method for high productivity fiber optic, metallurgical and semiconductor polishing that overcomes the problems of prior art.

### SUMMARY OF THE INVENTION

Accordingly, it is a principal object of the present invention to provide a thermoelectric device with improved heat dissipation characteristics.

It is another object of the present invention to provide a thermoelectric device with a high coefficient of performance (COP).

It is yet another object of the present invention to provide a thermoelectric device with improved distribution of heat accumulation.

It is yet another object of the present invention to provide a thermoelectric device with optimum distances between the cold pole and the heat sinks.

It is still another object of the present invention to provide a thermoelectric device with high conductivity for electric current and low conductivity for heat.

A thermoelectric device is described including:

a plurality of N-type thermoelectric semiconductor elements;

a plurality of P-type thermoelectric semiconductor elements;

metal junctions between horizontally adjacent semiconductor elements;

special layers between vertically adjacent N-type thermoelectric semiconductor elements and between vertically adjacent P-type thermoelectric semiconductor elements;

a cold pole;

at least two heat sinks;

and a source of direct current power interconnected so as to pump electrons from the N-type semiconductors to the P-type semiconductors, or to pump holes from the P-type semiconductors to the N-type semiconductors,

such that the heat buildup is distributed among more than one heat sink.

The device according has dimensions such that the width of each of the at least two heat sinks is substantially greater than the width of the cold pole; the corresponding area of each of the at least two heat sinks is substantially greater than the corresponding area of the cold pole; and the distance from the cold pole to each of the at least two heat sinks is substantially greater than the height of the semiconductor elements.

The track of the electric current is:

(a) N-type semiconductors;

(ii) special layers;

(iii) N-type semiconductors;

(iv) special layers;

(v) metal junction;

(vi) P-type semiconductors;

(vii) special layers;

(viii) metal junction;

(ix) special layers; and

(x) P-type semiconductors.

The at least two heat sinks are composed of standard aluminum alloys, and a thin film base is interposed between the at least two heat sinks.

Other features and advantages of the invention will become apparent from the following drawings and description.

### BRIEF DESCRIPTION OF THE DRAWINGS

For a better understanding of the invention with regard to the embodiments thereof, reference is made to the accompanying drawings, in which like numerals designate corresponding elements or sections throughout, and in which:

Prior art FIG. 1a is a combined graph and schematic diagram of thermoelectric heating.

Prior art FIG. 1b is a simplified schematic illustration of a standard Peltier module 100.

Prior art FIG. 1c is a schematic diagram of the electricity path 170 through standard module 100.

FIG. 2a is a simplified schematic illustration of an improved Peltier module in accordance with an exemplary embodiment of the present invention;

FIG. 2b is a schematic diagram of the electricity path through an improved Peltier module, in accordance with an exemplary embodiment of the present invention;

FIG. 3a is a schematic diagram of a top view for an improved Peltier module, in accordance with an exemplary embodiment of the present invention;

FIG. 3b is a schematic diagram of a side view for an improved Peltier module, in accordance with an exemplary embodiment of the present invention; and

FIG. 3c is a schematic diagram of a bottom view for an improved Peltier module, in accordance with an exemplary embodiment of the present invention.

It will be appreciated that the embodiments described as follows are cited by way of example, and that the present invention is not limited to what is particularly shown and described. Rather, the scope of the present invention, as defined by appended claims, includes both combinations and sub-combinations of the various features described, as well as variations and modifications thereof, which would occur to persons skilled in the art upon reading the descriptions, and which are not disclosed in the prior art.

### DETAILED DESCRIPTION OF EXEMPLARY EMBODIMENTS

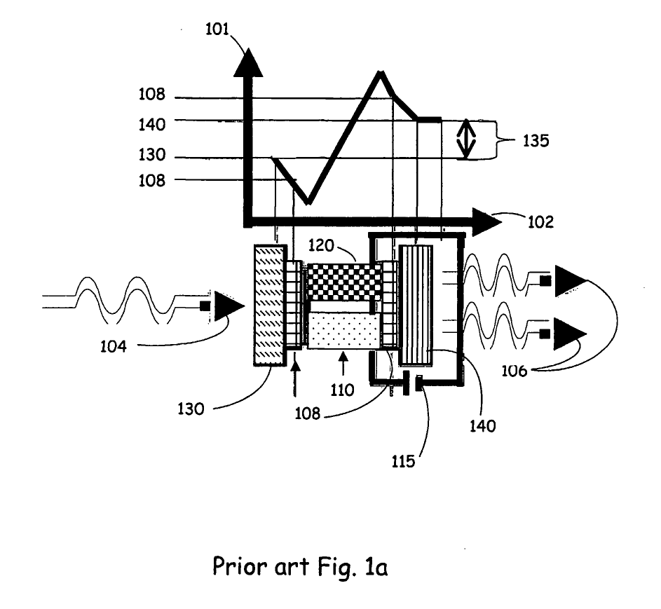

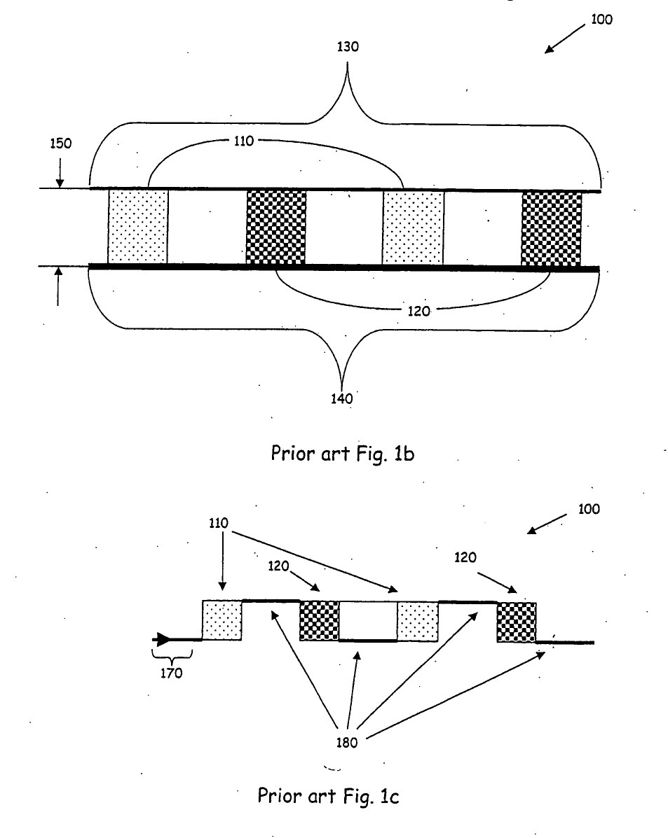

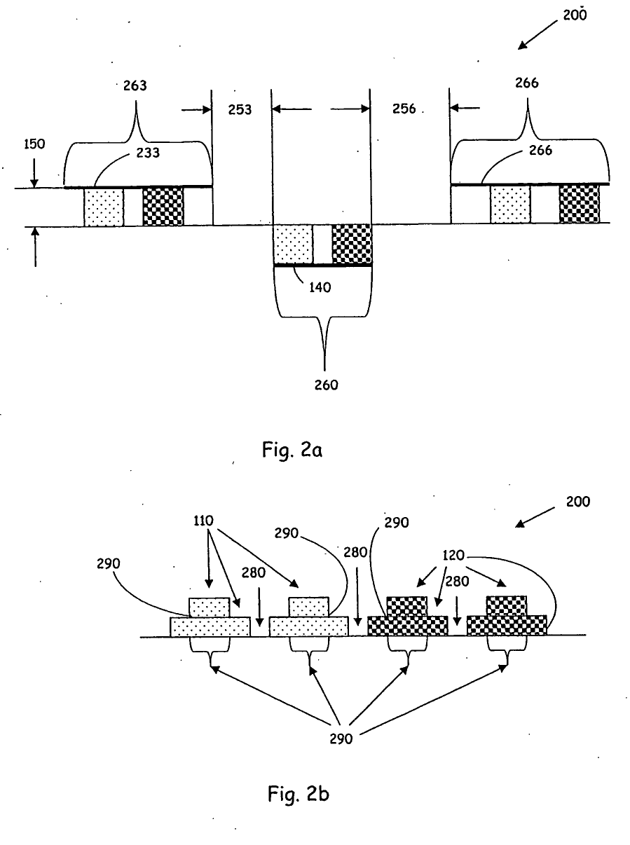

FIG. 2a is simplified schematic illustration of an improved Peltier module 200 in accordance with an exemplary embodiment of the present invention. There are now two heat sinks, a heat sink #1 233 and a heat sink #2 236. The width 263 of heat sink #1 233, and hence its corresponding area, is considerably greater than the width 260 of cold pole 140, and its corresponding area. Similarly, the width 266 of heat sink #2 236, and hence its corresponding area, is considerably greater than the width 260 of cold pole 140, and its corresponding area. The distance from cold pole 140 to heat sink #1 233 and heat sink #2 236 is considerably greater than the height of semiconductor elements 110 and 120.

FIG. 2b is a schematic diagram of the electricity path through improved Peltier module 200, in accordance with an exemplary embodiment of the present invention. The track of the electric current is N-type semiconductors 110—special layers 290—N-type semiconductors 110—special layers 290—metal junction 280—P-type semiconductors 120—special layers 290—metal junction 280—special layers 290— and P-type semiconductors 120.

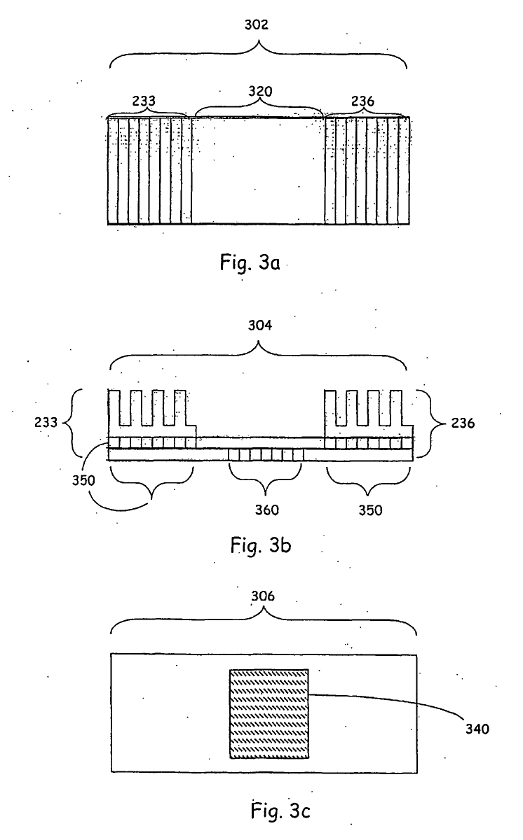

FIG. 3a is a schematic diagram of a top view for an improved Peltier module, in accordance with an exemplary embodiment of the present invention. Top view 302 shows heat sink #1 233 and heat sink #2 236, which are composed, for example of standard aluminum alloys. Between these heat sinks is a thin film base 320.

FIG. 3b is a schematic diagram of a side view for an improved Peltier module, in accordance with an exemplary embodiment of the present invention. The profile and height of heat sinks 233 and 236 are referenced in side view 304, as are the Peltier elements of each heat sink. Reference block 360 indicates the electrical interconnections on the base of the thin copper film.

FIG. 3c is a schematic diagram of a bottom view for an improved Peltier module, in accordance with an exemplary embodiment of the present invention. Bottom view 306 shows the orientation of cold pole 340.

We claim:

1. A thermoelectric device useful for cooling comprising:
a plurality of N-type thermoelectric semiconductor elements;
a plurality of P-type thermoelectric semiconductor elements;
metal junctions between horizontally adjacent semiconductor elements;
special layers between vertically adjacent N-type thermoelectric semiconductor elements and between vertically adjacent P-type thermoelectric semiconductor elements;
a cold pole;
at least two heat sinks;
and a source of direct current power interconnected so as to pump electrons from the N-type semiconductors to the P-type semiconductors, or to pump holes from the P-type semiconductors to the N-type semiconductors,
such that the heat buildup is distributed among more than one heat sink.

2. A device according to claim 1, wherein the width of each of the at least two heat sinks is substantially greater than the width of the cold pole.

3. A device according to claim 2, wherein the corresponding area of each of the at least two heat sinks is substantially greater than the corresponding area of the cold pole.

4. A device according to claim 1, wherein the distance from the cold pole to each of the at least two heat sinks is substantially greater than the height of the semiconductor elements.

5. A device according to claim 1, wherein the track of the electric current is:
(a) N-type semiconductors;
i. special layers;
ii. N-type semiconductors;
iii. special layers;
iv. metal junction;
v. P-type semiconductors;
vi. special layers;
vii. metal junction;
viii. special layers; and
ix. P-type semiconductors.

6. A device according to claim 1, wherein the at least two heat sinks are composed of standard aluminum alloys.

7. A device according to claim 1, wherein a thin film base is interposed between the at least two heat sinks.
